(19) United States
(12) Patent Application Publication
(10) Pub. No.: US 2026/0150191 A1
(43) Pub. Date: May 28, 2026

(54) PRINTED CIRCUIT BOARD MODULE AND ELECTRONIC DEVICE

(71) Applicant: LG INNOTEK CO., LTD., Seoul (KR)

(72) Inventors: Seung Hyeong LEE, Seoul (KR); Dong Joon KIM, Seoul (KR)

(21) Appl. No.: 19/453,152

(22) Filed: Jan. 20, 2026

Related U.S. Application Data
(62) Division of application No. 18/560,741.

(30) Foreign Application Priority Data
Jun. 24, 2021 (KR) 10-2021-0082697
Jan. 3, 2022 (KR) 10-2022-0000600

(51) Int. Cl. H05K 1/11; H05K 1/181; H05K 3/341

(52) U.S. Cl. CPC H05K 1/11; H05K 1/181; H05K 3/341; H05K 2201/032

(57) ABSTRACT

The printed circuit board module comprises: a printed circuit board including a first area

and a second area; an electronic component disposed in the first area; and a partition line disposed between the first area and the second area, wherein the partition line is disposed to be stepped with respect to a surface of the printed circuit board.

### CROSS-REFERENCE TO RELATED PATENT APPLICATIONS

This application is a divisional of U.S. patent application Ser. No. 18/560,741, filed Nov. 14, 2023, which is a National Stage Application under 35 U.S.C. § 371 of PCT Application No. PCT/KR2022/009023, filed Jun. 24, 2022, which claims priority to Korean Patent

Application Nos. 10-2021-0082697, filed Jun. 24, 2021 and 10-2022-0000600, filed Jan. 3, 2022, whose entire disclosures are hereby incorporated by reference.

### TECHNICAL FIELD

The present embodiment relates to a printed circuit module and an electronic device.

### BACKGROUND ART

Engine electrical devices (starting devices, ignition devices, and charging devices) and lighting devices are common as automobile electrical devices, but recently, most systems, including chassis electrical devices, are becoming electrically electronic as vehicles become more electronically controlled.

Various electrical components such as lamps, audio systems, heaters, and air conditioners installed in automobiles are designed to receive power from the battery when the car is stopped and from the generator when driving, and at this time, the generation capacity of the 14V power system is used as a normal power supply voltage.

Recently, along with the development of the information technology industry, various new technologies (motor-type power steering, Internet, and the like) aimed to enhance the convenience of automobiles are being adopted by vehicles, and in the future, it is expected that the development of new technologies that can maximally utilize the current automotive systems will continue.

A large number of electronic components are disposed inside an electrical component. As an example, the electronic component may include a printed circuit board. The printed circuit board is disposed inside a housing that forms the external shape of the electrical component.

At least one element is disposed or mounted on the printed circuit board. The device is soldered onto the printed circuit board for electrical connection. The printed circuit board includes a coated area and a non-coated area other than the coated area, and the area where the device is disposed may be a non-coated area for soldering.

However, a printed circuit board according to the prior art has a problem in that it is difficult to distinguish between a coated area and a non-coated area, which reduces production efficiency.

### DETAILED DESCRIPTION OF THE INVENTION

### Technical Subject

The present embodiment is intended to provide a printed circuit board module and an electronic device that can immediately distinguish between coated area and non-coated area and prevent a coating liquid from being spread through the non-coated area.

In addition, it is intended to provide an electronic device that can firmly fix electronic components to a printed circuit board by minimizing the space occurring between the pad and solder of the printed circuit board.

### Technical Solution

A printed circuit board module according to the present embodiment comprises: a printed circuit board including a first area and a second area; an electronic component being disposed in the first area; and a partition line being disposed between the first area and the second area, wherein the partition line is disposed to be stepped with respect to a surface of the printed circuit board.

The second area may be an area where the coating liquid is applied, and the first area may be an area where the electronic component is soldered.

The partition line may include a plurality of lines being disposed radially about the electronic component.

A gap may be formed between adjacent lines among the plurality of lines so as to be spaced apart from one another.

The spacing between adjacent lines among the plurality of lines may be smaller than the thickness of each line.

The thickness of each line is 0.2 mm to 0.4 mm, and the spacing between adjacent lines may be 0.05 mm to 0.15 mm.

The plurality of lines may include: a first line being disposed outside the electronic component; a second line being disposed outside the first line; and a third line being disposed outside the second line.

The material of the partition line may be silk.

The electronic component and the partition line may be spaced apart from each other.

The electronic device according to the present embodiment includes: a housing; and a printed circuit board module being disposed inside the housing, wherein the printed circuit board module includes: a printed circuit board including a first area and a second area; an electronic component being disposed in the first area; and a partition line being disposed between the first area and the second area, and wherein the partition line is disposed to be stepped with respect to a surface of the printed circuit board.

### Advantageous Effects

Through the present embodiment, it is possible to prevent the coating solution from being spread through non-coated area when applying the coating solution to coated area due to the effect of being stepped with respect to a surface of the printed circuit board through a partition line.

In addition, the coating liquid can be prevented from spreading to other areas due to the difference in surface resistance between the solder area and the partition line made of silk on a printed circuit board.

In addition, the space being formed between the pad and solder during the surface mount technology (SMT) process can be minimized, and the bonding force between the pad and solder can be maximized. Accordingly, there is an advantage in preventing the separation of electronic components coupled to a printed circuit board.

### BRIEF DESCRIPTION OF DRAWINGS

FIG. 1 is a plan view of a printed circuit board module according to a first embodiment of the present invention.

FIGS. 2 and 3 are diagrams showing the process of applying a coating liquid on a printed circuit board module according to a first embodiment of the present invention.

FIG. 4 is a plan view of a printed circuit board module according to a first embodiment of the present invention.

FIG. 5 is a cross-sectional view taken along line A-A′ of FIG. 4.

FIG. 6 is a cross-sectional view of a printed circuit board module according to the prior art.

FIG. 7 is a diagram illustrating a pad coupled to a printed circuit board according to a second embodiment of the present invention.

FIG. 8 is a diagram illustrating the formation of a first-first groove and a first-second groove in a pad according to a second embodiment of the present invention.

FIG. 9 is a view illustrating the formation of a third groove and a fourth groove in a pad according to a third embodiment of the present invention.

FIG. 10 is a diagram illustrating the formation of a fifth groove and a sixth groove in a pad according to a fourth embodiment of the present invention.

FIG. 11 is a view illustrating the formation of a seventh groove, an eighth groove, and a ninth groove in a pad according to a fifth embodiment of the present invention.

FIG. 12 is a view illustrating the formation of a tenth groove, an eleventh groove, and a twelfth groove in a pad according to a sixth embodiment of the present invention.

### BEST MODE

Hereinafter, preferred embodiments of the present invention will be described in detail with reference to the accompanying drawings.

However, the technical idea of the present invention is not limited to some embodiments to be described, but may be implemented in various forms, and inside the scope of the technical idea of the present invention, one or more of the constituent elements may be selectively combined or substituted between embodiments.

In addition, the terms (including technical and scientific terms) used in the embodiments of the present invention, unless explicitly defined and described, can be interpreted as a meaning that can be generally understood by a person skilled in the art, and commonly used terms such as terms defined in the dictionary may be interpreted in consideration of the meaning of the context of the related technology.

In addition, terms used in the present specification are for describing embodiments and are not intended to limit the present invention. In the present specification, the singular form may include the plural form unless specifically stated in the phrase, and when described as “at least one (or more than one) of A and B and C”, it may include one or more of all combinations that can be combined with A, B, and C.

In addition, in describing the components of the embodiment of the present invention, terms such as first, second, A, B, (a), and (b) may be used.

These terms are merely intended to distinguish the components from other components, and the terms do not limit the nature, order or sequence of the components.

And, when a component is described as being ‘connected’, ‘coupled’ or ‘interconnected’ to another component, the component is not only directly connected, coupled or interconnected to the other component, but may also include cases of being ‘connected’, ‘coupled’, or ‘interconnected’ due that another component between that other components.

In addition, when described as being formed or disposed in “on (above)” or “below (under)” of each component, “on (above)” or “below (under)” means that it includes not only the case where the two components are directly in contact with, but also the case where one or more other components are formed or disposed between the two components. In addition, when expressed as “on (above)” or “below (under)”, the meaning of not only an upward direction but also a downward direction based on one component may be included.

The electronic device according to the present embodiment is provided inside a vehicle and may include an electronic control unit, a pump, a converter and the like. However, this is an exemplary example, and an electrical device according to the present specification may include various devices in which at least one or more electronic component is disposed inside a housing.

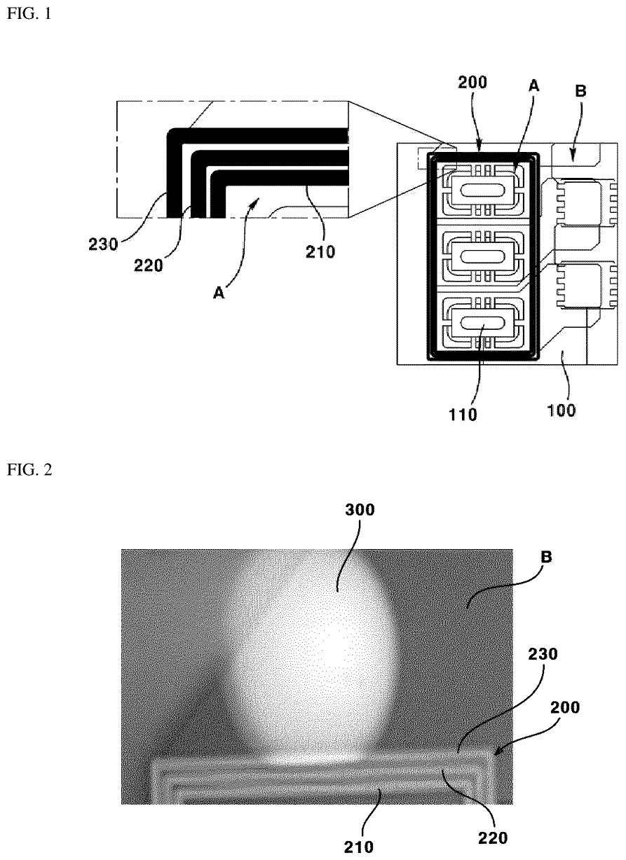

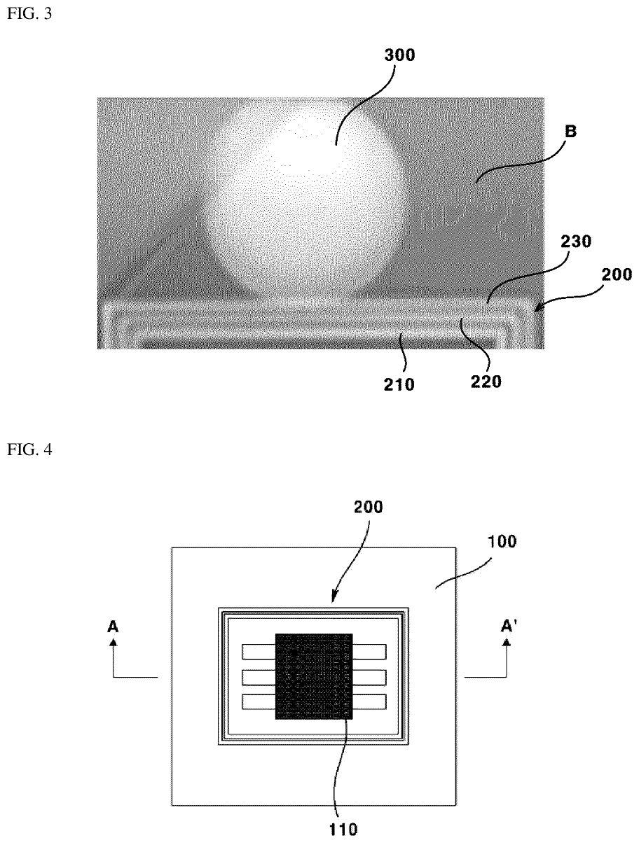

FIG. 1 is a plan view of a printed circuit board module according to a first embodiment of the present invention; and FIGS. 2 and 3 are diagrams showing the process of applying a coating liquid on a printed circuit board module according to a first embodiment of the present invention.

Referring to FIGS. 1 to 3, a printed circuit board module according to a first embodiment of the present invention may be disposed inside a housing (not shown) that forms the external shape of an electronic device.

The printed circuit board module may include a printed circuit board 100 and an electronic component 110.

The printed circuit board 100 is formed in a plate shape, and at least one or more electronic component (element) may be disposed on an upper surface or a lower surface. The electronic component may be soldered on an outer surface of the printed circuit board 100 and thus may be electrically connected to the printed circuit board 100 or other electronic components.

The printed circuit board 100 may include a coated area B and a non-coated area A. The coated area B may be an area where a coating liquid is applied. The non-coated area A is an area other than the coated area B on an outer surface of the printed circuit board 100 and may be an area where a coating liquid is not applied. As illustrated in FIG. 1, the area on the surface of the printed circuit board 100 where the electronic component 110 is disposed may be a non-coated area A on the printed circuit board 100 where no coating liquid is applied for soldering.

The non-coated area A can be referred to as a first area, and the coated area B can be referred to as a second area.

A partition line 200 may be disposed on a surface of the printed circuit board 100 to partition the coated area B and the non-coated area A. The partition line 200 may be disposed outside the electronic component 100 being soldered on the printed circuit board 100. The partition line 200 may be disposed along the circumference of the electronic component 100. The partition line 200 is spaced apart from the electronic component 100 by a predetermined distance, and the electronic component 100 may be disposed inside the partition line 200.

The partition line 200 is made of silk and may have a shape being protruded from a surface of the printed circuit board 100. For example, when the partition line 200 is disposed on an upper surface of the printed circuit board 100, the upper surface of the partition line 200 may be disposed to be stepped more upward than the upper surface of the printed circuit board 100. As another example, when the partition line 200 is disposed on a lower surface of the printed circuit board 100, the lower surface of the partition line 200 may be disposed to be stepped more downward than the lower surface of the printed circuit board 100.

The coated area B and the non-coated area A can be immediately distinguished on the printed circuit board 100 through the partition line 200. At an inner side of the partition line 200, a plurality of electronic components 110 being soldered on the printed circuit board 100 may be disposed.

The partition line 200 may have a rectangular cross-sectional shape as illustrated in FIG. 1. However, this is an exemplary example, and the partition line 200 may be formed in various shapes, including circular.

The partition line 200 may include a plurality of lines. The plurality of lines may be disposed radially about the electronic component 110. For example, the partition line 200 may include a first line 210, a second line 220 being disposed at an outer side of the first line 210, and a third line 230 being disposed at an outer side of the second line 220. The first to third lines 210, 220, and 230 are disposed to be spaced apart from one another, and a gap may be formed between adjacent lines among the plurality of lines.

More specifically, the gap between adjacent lines among the plurality of lines 210, 220, and 230 may be smaller than the thickness of each line. The thickness of each of the lines 210, 220, and 230 may be three times or more than the spacing between adjacent lines. As an example, the thickness of each of the lines 210, 220, and 230 may be 0.2 mm to 0.4 mm, and the spacing between adjacent lines may be 0.05 mm to 0.15 mm.

According to the structure as described above, due to the effect of being stepped with respect to a surface of the printed circuit board 100 through the partition line 200, when applying a coating liquid to the coated area B, spreading of the coating liquid through the non-Coated area a can be prevented.

In addition, the coating liquid can be prevented from spreading to other areas due to the difference in surface resistance between the solder area on the printed circuit board 100 and the partition line 200 made of silk.

FIG. 2 is a photograph taken 5 seconds after applying the coating liquid to a coated area B adjacent to the partition line 200, and FIG. 3 is a photograph taken 18 hours after applying the coating liquid to the coated area B adjacent to the partition line 200.

As shown in FIGS. 2 and 3, even if the coating liquid is applied to the coated area B adjacent to the partition line 200, spreading of coating liquid through the non-coated area A can be prevented by the partition line 200. In particular, even after 18 hours for complete curing of the coating liquid, the coating liquid can only flow up to the gap area between adjacent lines due to the multiple line structure of the partition line 200, so it can be seen that the spreading through the non-Coated area a is completely blocked.

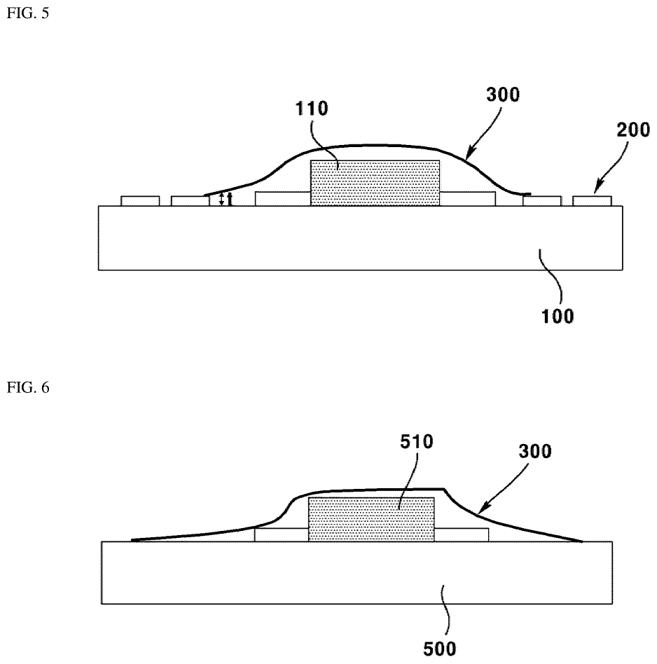

FIG. 4 is a plan view of a printed circuit board module according to a first embodiment of the present invention; FIG. 5 is a cross-sectional view taken along line A-A′ of FIG. 4; and FIG. 6 is a cross-sectional view of a printed circuit board module according to the prior art.

Referring to FIGS. 4 and 5, in a printed circuit board module according to the present embodiment, when applying coating liquid 300 to the non-coated area A after the soldering process of the electronic component 110, a coated area with a certain thickness t may be formed in an edge area of the non-coated area A adjacent to the partition line 200 by the partition line 200. This is an effect that the coating liquid 30 applied in the non-coated area A is also prevented from spreading through the coated area B by the partition line 200.

In addition, at least a portion of the coated area inside the arrangement area of the electronic component 110 through the partition line 200 may have an area equal to the thickness of the partition line 110.

However, referring to FIG. 6, in the case of a printed circuit board module according to the prior art, since there is no separate partition line to prevent the flow of coating liquid, there is a problem in securing a uniform coating thickness due to the spreading phenomenon of the coating liquid.

Meanwhile, in the present specification, an area where the electronic component 110 is disposed within the printed circuit board 100 is defined as a non-coated area A, and an area other than the non-coated area A is defined as a coated area B and explained, but is not limited thereto, and the area where the electronic component 110 is disposed is formed as a coated area while the other area is formed as a non-coated area, so that a partition line 200 may be disposed between the coated area and the non-coated area.

Hereinafter, an electronic device according to a second embodiment will be described.

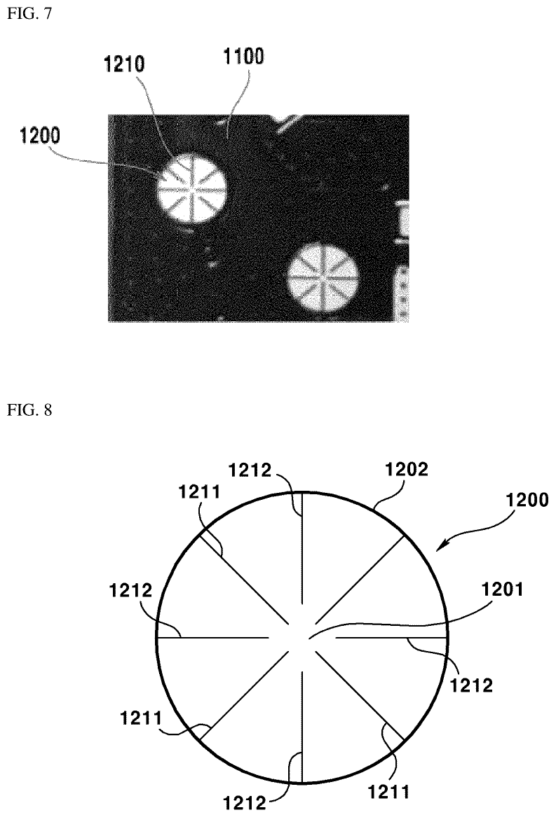

FIG. 7 is a diagram illustrating a surface of a printed circuit board according to a second embodiment of the present invention; and FIG. 8 is a diagram illustrating a surface of a pad according to a second embodiment of the present invention. Referring to FIGS. 7 and 8, the electronic device according to the second embodiment of the present invention may include a housing (not shown) or a bracket (not shown), a printed circuit board 1100, a pad 1200, an electronic component (not shown), and a solder (not shown).

A printed circuit board 1100 may be coupled to the housing or bracket. The housing or bracket may include an area where the printed circuit board 1100 is disposed. For example, a space in which the printed circuit board 1100 is disposed may be formed inside the housing, or an installation surface to which the printed circuit board 1100 is coupled may be formed on a surface of the bracket.

A circuit pattern may be disposed on a surface of the printed circuit board 1100. The printed circuit board 1100 may include a hole (not shown) penetrating from one surface of the printed circuit board 1100 to the other surface. The hole may be a hole into which a screw is inserted. The hole may be a hole into which at least a portion of the electronic component is inserted. The printed circuit board 1100 may be coupled to the space of the housing or the installation surface of the bracket through a screw being inserted into the hole.

Electronic components may be disposed on one surface or the other surface of the printed circuit board 1100. The pad 1200 may be disposed on one surface or the other surface of the printed circuit board 1100. The pad 1200 may be disposed on one surface and the other surface of the printed circuit board 1100. At least a portion of an electronic component may be coupled to the pad 1200 being disposed in the printed circuit board 1100.

The pad 1200 may be disposed on a surface of the printed circuit board 1100. The pad 1200 may be disposed on one surface or the other surface of the printed circuit board 1100. The pad 1200 may be disposed on one surface and the other surface of the printed circuit board 1100. A plurality of pads 1200 may be provided. The plurality of pads 1200 may be disposed to be spaced apart from one another on a surface of the printed circuit board 1100. The pad 1200 may include a base member and a surface layer. The surface layer may be formed on a surface of the base member. The material of the base member may be copper. The material of the surface layer may be gold or silver. The pad 1200 may have a circular cross-section.

A groove may be formed on one surface of the pad 1200. At least a portion of an electronic component may be disposed on one surface of the pad 1200. The other surface of the pad 1200 may face the surface of the printed circuit board 1100. The other surface of the pad 1200 may be coupled to the surface of the printed circuit board 1100.

A first groove 1210 may be formed on one surface of the pad 1200. The first groove 1210 may have a straight line shape. The first groove 1210 may also be referred to as a straight line groove. The pad 1200 may be divided into multiple areas by the first groove 1210. The plurality of areas may be disposed along a circumferential direction. The first groove 1210 may be formed so that one end faces the center 1201 of the pad 1200. One end of the first groove 1210 may be disposed to be spaced apart from the center 1201 of the pad 1200. The first groove 1210 may be formed so that the other end faces the outer side of the pad 1200 in a radial direction. The first groove 1210 can be formed by the other end by being extended to the edge area 1202 of the pad 1200. A plurality of first grooves 1210 may be formed. The plurality of first grooves 1210 may be disposed radially with respect to the center 1201 of the pad 1200. The plurality of first grooves 1210 may be disposed to be spaced apart from one another in a circumferential direction.

The plurality of first grooves 1210 may have different lengths. For example, the lengths of the plurality of first grooves 1210 being disposed to be adjacent to one another in a circumferential direction may be different from one another. In this case, a first groove 1210, which is relatively long in length, is referred to as a first-first groove 1211, and a first groove 1210, which is relatively short in length, may be referred to as a first-second groove 1212. The first-second groove 1212 may be disposed between the pluralities of first-first grooves 1211. The first-first groove 1211 may be disposed between the pluralities of first-second grooves 1212. The first-first grooves and the first-second grooves may be disposed alternately along the circumferential direction. One end of the first-first groove 1211 may be disposed closer to the center of the pad 1200 than one end of the first-second groove 1212.

According to the above structure, bubbles being generated in the process of melting the solder being disposed on one surface of the pad 1200 during the surface mount technology (SMT) process may flow along the first-first groove 1211 or the first-second groove 1212. Since the other end of the first-first groove 1211 or the first-second groove 1212 is extended to the edge area 1202 of the pad 200, as long as solder is not formed up to the area beyond the pad 1200, the bubbles will flow along the first-first groove 1211 or the first-second groove 1212 and may be discharged to the outside of the pad 1200. Accordingly, the space being formed between the pad 1200 and the solder is reduced, so that the coupling between the pad 1200 and the solder can be firmly maintained.

Hereinafter, the pad for a third embodiment will be described.

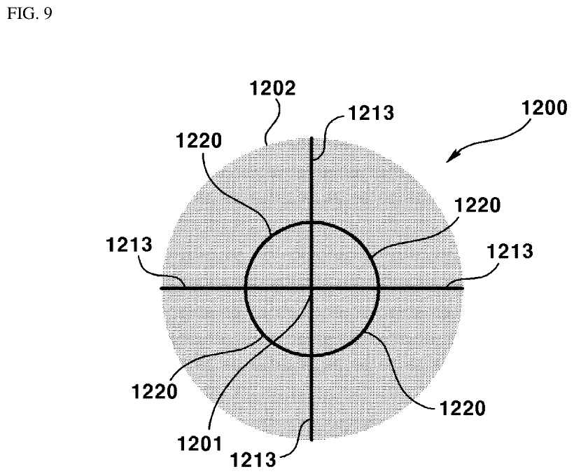

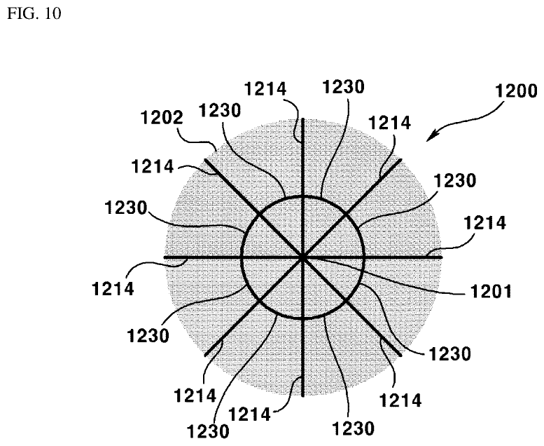

FIG. 9 is a view illustrating the surface of a pad according to a third embodiment of the present invention.

The present embodiment is the same as the second embodiment in other respects, but there is a difference according to the arrangement of the grooves within the pad. Therefore, hereinafter, only the characteristic parts of the present embodiment will be described, and the description of the second embodiment will be used for the remaining parts.

Referring to FIG. 9, the pad 1200 of the electronic device according to a third embodiment of the present invention may include a third groove 1213 and a fourth groove 1220.

A third groove 1213 may be formed on one surface of the pad 1200. The third groove 1213 may have a straight line shape. The third groove 1213 may also be referred to as a straight line groove. The pad 1200 may be divided into multiple areas by the third groove 1213. The multiple areas may be disposed along a circumferential direction. The third groove 1213 may be disposed so that one end faces the center 1201 of the pad 1200. The third groove 1213 may be disposed to be connected to the center 1201 of the pad 1200 in a radial direction. The third groove 1213 may be formed so that the other end faces the outer side of the pad 1200 in a radial direction. The third groove 1213 can be formed by the other end by being extended to the edge area 1202 of the pad 1200. A plurality of third grooves 1213 may be formed. The plurality of third grooves 1213 may be disposed radially with respect to the center 1201 of the pad 1200. The plurality of third grooves 1213 may be disposed to form an angle of 90° in a circumferential direction. In other words, it may be understood that a plurality of third grooves 1213 is provided and disposed to be crossed with one another.

A fourth groove 1220 may be formed on one surface of the pad 1200. The fourth groove 1220 may have a curved shape. The fourth groove 1220 may also be referred to as a curved groove. The center of the radius of curvature of the fourth groove 1220 may correspond to the center 1201 of the pad 1200. The fourth groove 1220 may have an arc shape. The center angle of an arc of the fourth groove 1220 may be 90°. The fourth groove 1220 may be formed to be spaced outward from the center 1201 of the pad 1200 in a radial direction. The fourth groove 1220 may be formed between the pluralities of third grooves 1213. The fourth groove 1220 may be formed between the pluralities of third grooves 1213 being disposed adjacent to one another. Both ends of the fourth groove 1220 may be connected to the pluralities of third grooves 1213 being disposed adjacent to one another. The pluralities of fourth grooves 1220 may be formed in the radial direction of the pad to form a concentric circle with the pad 1200.

According to the above structure, bubbles being generated in the process of melting the solder being disposed on one surface of the pad 1200 during the surface mount technology (SMT) process may flow along the third groove 1213. Since the other end of the third groove 1213 is extended to the edge area 1202 of the pad 1200, as long as solder is not formed up to the area beyond the pad 1200, the bubbles will flow along the third groove 1213 and may be discharged to the outside of the pad 1200.

In addition, the bubbles may be formed in an area between the third grooves 1213 being formed radially on the pad 1200 with respect to the center 1201 of the pad 1200. That is, the bubbles may be formed between pluralities of third grooves 1213 being adjacent to each other. In this case, the fourth groove 1220 is formed between the pluralities of third grooves 1213 being adjacent to one another, and since both ends of the fourth groove 1220 are formed to be connected to the pluralities of third grooves 1213, the bubbles flow along the fourth groove 1220 and can be introduced into the third groove 1213. Air bubbles being introduced into the third groove 1213 may flow to the other end of the third groove 1213 and be discharged to the outside of the pad 1200. Accordingly, the space being formed between the pad 1200 and the solder is reduced, so that the coupling between the pad 1200 and the solder can be firmly maintained.

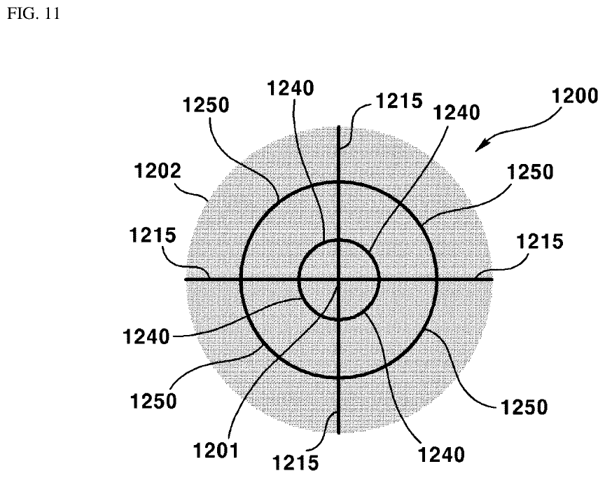

FIG. 10 is a diagram illustrating the surface of a pad according to a fourth embodiment of the present invention.

Hereinafter, the pad for a fourth embodiment will be described. The present embodiment is the same as the second embodiment in other respects, but there is a difference according to the arrangement of the grooves inside the pad. Therefore, hereinafter, only the characteristic parts of the present embodiment will be described, and the description of the second embodiment will be used for the remaining parts.

Referring to FIG. 10, a pad 1200 of the electronic device according to a fourth embodiment of the present invention may include a fifth groove 1214 and a sixth groove 1230.

A plurality of fifth grooves 1214 may be formed on one surface of the pad 1200. The fifth groove 1214 may have a straight line shape. The fifth groove 1214 may also be referred to as a straight line groove. The pad 1200 may be divided into multiple areas by the fifth groove 1214. The multiple areas may be disposed along a circumferential direction. The fifth groove 1214 may be disposed so that one end faces the center 1201 of the pad 1200. The fifth groove 1214 may be disposed to be connected to the center 1201 of the pad 1200 in a radial direction. The fifth groove 1214 may be formed so that the other end faces the outer side of the pad 1200 in a radial direction. The fifth groove 1214 can be formed by the other end by being extended to the edge area 1202 of the pad 1200. A plurality of fifth grooves 1214 may be formed. The plurality of fifth grooves 1214 may be radially disposed with respect to the center 1201 of the pad 1200. The plurality of fifth grooves 1214 may be disposed to form an angle of 45° in a circumferential direction.

A sixth groove 1230 may be formed on one surface of the pad 1200. The sixth groove 1230 may have a curved shape. The center of the radius of curvature of the sixth groove 1260 may correspond to the center 1201 of the pad 1200. The sixth groove 1230 may have an arc shape. The sixth groove 1230 may have an arc shape with a central angle of 45°. The sixth groove 1230 may be formed to be spaced apart from the center 1201 of the pad 1200 toward the outer side of the pad 1200 in a radial direction. The sixth groove 1230 may be formed between the pluralities of fifth grooves 1214. The sixth groove 1230 may be formed between the pluralities of fifth grooves 1214 being disposed adjacent to one another. Both ends of the sixth groove 1230 may be connected to the plurality of adjacent fifth grooves 1214. A plurality of sixth grooves 1230 may be formed in a radial direction of the pad to form a concentric circle with the pad 1200.

According to the above structure, bubbles being generated in the process of melting the solder being disposed on one surface of the pad 1200 during the surface mount technology (SMT) process may flow along the fifth groove 1214. Since the other end of the fifth groove 1214 is extended to the edge area 1202 of the pad 1200, as long as solder is not formed up to the area beyond the pad 1200, the bubbles will flow along the fifth groove 1214 and may be discharged to the outside of the pad 1200.

In addition, the bubbles may be formed in an area between the fifth grooves 1214 being radially formed on the pad 1200 with respect to the center 1201 of the pad 1200. That is, the bubbles may be formed between the pluralities of fifth grooves 1214 being adjacent to one another. In this case, the sixth groove 1230 is formed between the pluralities of adjacent fifth grooves 1214, and both ends of the sixth groove 1230 are connected to the pluralities of fifth grooves 1214. Therefore, the bubbles flow along the sixth groove 1230 and may be introduced into the fifth groove 1214. Air bubbles being introduced into the fifth groove 1214 may flow to the other end of the fifth groove 1214 and be discharged to the outside of the pad 1200. Accordingly, the space formed between the pad 1200 and the solder is reduced, so that the coupling between the pad 1200 and the solder can be firmly maintained.

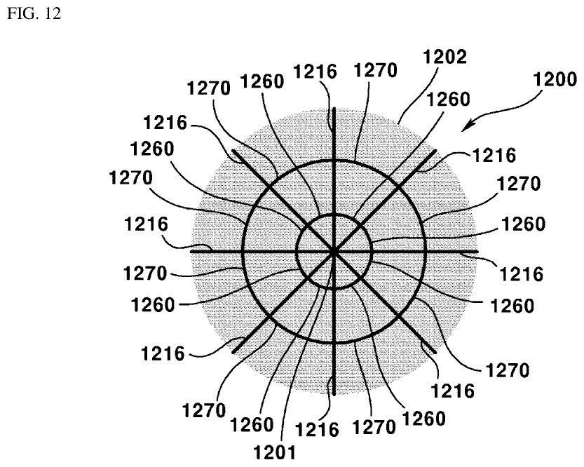

FIG. 11 is a diagram illustrating the surface of a pad according to a fifth embodiment of the present invention.

Hereinafter, the pad for a fourth embodiment will be described. The present embodiment is the same as the second embodiment in other respects, but there is a difference according to the arrangement of the grooves inside the pad. Therefore, hereinafter, only the characteristic parts of the present embodiment will be described, and the description of the second embodiment will be used for the remaining parts.

Referring to FIG. 11, a pad 1200 of the electronic device according to a fifth embodiment of the present invention may include a seventh groove 1215, an eighth groove 1240, and a ninth groove 1250.

A seventh groove 1215 may be formed on one surface of the pad 1200. The seventh groove 1215 may have a straight line shape. The seventh groove 1215 may also be referred to as a straight line groove. The pad 1200 may be divided into multiple areas by the seventh groove 1215. The multiple areas may be disposed along a circumferential direction. The seventh groove 1215 may be disposed so that one end faces the center 1201 of the pad 1200. The seventh groove 1215 may be disposed to be connected to the center 1201 of the pad 1200 in a radial direction. The seventh groove 1215 may be formed so that the other end faces the outer side of the pad 1200 in a radial direction. The seventh groove 1215 can be formed by the other end by being extended to the edge area 1202 of the pad 1200. A plurality of seventh grooves 1215 may be formed. The plurality of seventh grooves 1215 may be radially disposed with respect to the center 1201 of the pad 1200. The plurality of seventh groove 1215 may be disposed to form an angle of 90°in a circumferential direction.

An eighth groove 1240 may be formed on one surface of the pad 1200. The eighth groove 1240 may have a curved shape. The eighth groove 1240 may also be referred to as a first curved groove. The center of the radius of curvature of the eighth groove 1240 may correspond to the center 1201 of the pad 1200. The eighth groove 1240 may have an arc shape. The eighth groove 1240 may have an arc shape with a central angle of 90°. The eighth groove 1240 may be formed to be spaced apart from the center 1201 of the pad 1200 toward the outer side of the pad 1200 in a radial direction. The eighth groove 1240 may be formed between pluralities of seventh grooves 1215 being disposed adjacent to one another. The eighth groove 1240 may be formed between the ninth groove 1250, which will be described later, and the center 1201 of the pad 1200. Both ends of the eighth groove 1240 may be formed to be connected to the pluralities of seventh grooves 1215 being adjacent to one another. The pluralities of eighth grooves 1240 may be formed in a radial direction of the pad to form a concentric circle with the pad 1200.

A ninth groove 1250 may be formed on one surface of the pad 1200. The ninth groove 1250 may have a curved shape. The ninth groove 1250 may also be referred to as a second curved groove. As for the ninth groove 1250, the center of the radius of curvature of the ninth groove 1250 may correspond to the center 1201 of the pad 1200. The ninth groove 1250 may have an arc shape. The ninth groove 1250 may be an arc whose center angle is 90°. The ninth groove 1250 may be formed to be spaced outward from the eighth groove 1240 in a radial direction. The ninth groove 1250 may be formed between pluralities of seventh grooves 1215. The ninth groove 1250 may be formed between the pluralities of seventh grooves 1215 being disposed adjacent to one another. Both ends of the ninth groove 1250 may be connected to the pluralities of seventh grooves 1215 being disposed to be adjacent to one another. The pluralities of ninth grooves 1250 may be formed in a radial direction of the pad to form a concentric circle with the pad 1200.

According to the above structure, bubbles being generated in the process of melting the solder being disposed on one surface of the pad 1200 during the surface mount technology (SMT) process may flow along the seventh groove 1215. Since the other end of the seventh groove 1215 is extended up to the edge area 1202 of the pad 1200, as long as solder is not formed up to the area beyond the pad 1200, the bubbles flow along the seventh groove 1215 and may be discharged to the outside of the pad 1200.

In addition, the bubbles may be formed in an area between the seventh grooves 1215 being radially formed on the pad 1200 with respect to the center 1201 of the pad 1200. That is, the bubbles may be formed between pluralities of seventh groove 1215 being adjacent to each other. In this case, the sixth groove 1230 is formed between the pluralities of adjacent seventh groove 1215, and since both ends of the sixth groove 1230 are connected to the pluralities of seventh grooves 1215, the bubbles flow along the sixth groove 1230 and may be introduced into the seventh groove 1215. Air bubbles being introduced into the seventh groove 1215 may flow to the other end of the seventh groove 1215 and be discharged to the outside of the pad 1200. Accordingly, the space formed between the pad 1200 and the solder is reduced, so that the coupling between the pad 1200 and the solder can be firmly maintained.

FIG. 12 is a diagram illustrating a surface of a pad according to a sixth embodiment of the invention.

Hereinafter, a pad for a sixth embodiment will be described.

This embodiment is the same as the second embodiment in other respects, but there is a difference according to the arrangement of the grooves within the pad. Therefore, hereinafter, only the characteristic parts of the present embodiment will be described, and the description of the second embodiment will be used for the remaining parts.

Referring to FIG. 12, a pad 1200 of an electronic device according to a sixth embodiment of the present invention may include a tenth groove 1216, an eleventh groove 1260, and a twelfth groove 1270.

A plurality of tenth grooves 1216 may be formed on one surface of the pad 1200. The tenth groove 1216 may have a straight line shape. The tenth groove 1216 may also be referred to as a straight line groove. The pad 1200 may be divided into multiple areas by the tenth groove 1216. The multiple areas may be disposed along a circumferential direction. The tenth groove 1216 may be disposed so that one end faces the center 1201 of the pad 1200. The tenth groove 1216 may be disposed to be connected to the center 1201 of the pad 1200 in a radial direction. The tenth groove 1216 may be formed so that the other end faces the outer side of the pad 1200 in a radial direction. The tenth groove 1216 can be formed by the other end by being extended to the edge area 1202 of the pad 1200. A plurality of tenth grooves 1216 may be formed in plural numbers. The plurality of tenth grooves 1216 may be disposed radially with respect to the center 1201 of the pad 1200. The plurality of tenth grooves 1216 may be disposed to form an angle of 45° in a circumferential direction.

An eleventh groove 1260 may be formed on one surface of the pad 1200. The eleventh groove 1260 may have a curved shape. The eleventh groove 1260 may also be referred to as a first curved groove. The center of the radius of curvature of the eleventh groove 1260 may correspond to the center 1201 of the pad 1200. The eleventh groove 1260 may have an arc shape. The eleventh groove 1260 may have an arc shape with a central angle of 45°. The eleventh groove 1260 may be formed to be spaced apart from the center 1201 of the pad 1200 toward the outer side of the pad 1200 in a radial direction. The eleventh groove 1260 may be formed between the pluralities of tenth grooves 1216 being disposed adjacent to one another. The eleventh groove 1260 may be formed between the twelfth groove 1260, which will be described later, and the center 1201 of the pad 1200. Both ends of the twelfth groove 1260 may be formed by being connected to the pluralities of adjacent tenth grooves 1216 being adjacent to one another. The pluralities of twelfth groove 1260 may be formed in a radial direction of the pad to form a concentric circle with the pad 1200.

A twelfth groove 1270 may be formed on one surface of the pad 1200. The twelfth groove 1270 may have a curved shape. The twelfth groove 1270 may also be called a second curved groove. The center of the radius of curvature of the twelfth groove 1270 may correspond to the center 1201 of the pad 1200. The twelfth groove 1270 may have an arc shape. The twelfth groove 1270 may have an arc shape with a central angle of 45°. The twelfth groove 1270 may be formed to be spaced apart from the eleventh groove 1260 in a radial direction. The twelfth groove 1270 may be formed between the pluralities of tenth grooves 1216. The twentieth groove 1270 may be formed between the pluralities of tenth grooves 1216 being disposed adjacent to one another. Both ends of the twelfth groove 1270 may be connected to the pluralities of adjacent tenth grooves 1216. The pluralities of twelfth grooves 1270 may be formed in a radial direction of the pad to form a concentric circle with the pad 1200. The eleventh groove 1260 and the twelfth groove 1270 may form concentric circles.

According to the above structure, bubbles being generated in the process of melting the solder being disposed on one surface of the pad 1200 during the surface mount technology (SMT) process may flow along the tenth groove 1216. Since the other end of the tenth groove 1216 is extended to the edge area 1202 of the pad 1200, as long as solder is not formed up to the area beyond the pad 1200, the bubbles flow along the tenth groove 1216 and may be discharged to the outside of the pad 1200.

In addition, the bubbles may be formed in an area between the tenth grooves 1216 being radially formed on the pad 1200 with respect to the center 1201 of the pad 1200. That is, the bubbles may be formed between the pluralities of tenth grooves 1216 being adjacent to each other. In this case, the eleventh groove 1260 or the twelfth groove 1270 is formed between the pluralities of adjacent tenth grooves 1216, and since both ends of the eleventh groove 1260 or the twelfth groove 1270 are formed by being connected to the pluralities of tenth grooves 1216, the bubbles flow along the eleventh groove 1260 or the twelfth groove 1270 and may be introduced into the tenth grooves 1216. Air bubbles being introduced into the tenth grooves 1216 flow to the other end of the tenth grooves 1216 and may be discharged to the outside of the pad 1200. Accordingly, the space formed between the pad 1200 and the solder is reduced, so that the coupling between the pad 1200 and the solder can be firmly maintained.

In the above description, it is described that all the components constituting the embodiments of the present invention are combined or operated in one, but the present invention is not necessarily limited to these embodiments. In other words, within the scope of the present invention, all of the components may be selectively operated in combination with one or more. In addition, the terms “comprise”, “include” or “having” described above mean that the corresponding component may be inherent unless specifically stated otherwise, and thus it should be construed that it does not exclude other components, but further include other components instead. All terms, including technical and scientific terms, have the same meaning as commonly understood by one of ordinary skill in the art unless otherwise defined. Terms used generally, such as terms defined in a dictionary, should be interpreted to coincide with the contextual meaning of the related art, and shall not be interpreted in an ideal or excessively formal sense unless explicitly defined in the present invention.

The above description is merely illustrative of the technical idea of the present invention, and those skilled in the art to which the present invention pertains may make various modifications and changes without departing from the essential characteristics of the present invention. Therefore, the embodiments disclosed in the present invention are not intended to limit the technical idea of the present invention but to describe the present invention, and the scope of the technical idea of the present invention is not limited by these embodiments. The protection scope of the present invention should be interpreted by the following claims, and all technical ideas within the equivalent scope should be interpreted as being included in the scope of the present invention.

1. An electronic device comprising:
a printed circuit board; and
a pad disposed on a surface of the printed circuit board,
wherein the pad includes a plurality of straight grooves formed on one surface thereof, and
wherein the plurality of straight grooves are arranged radially with respect to a center of the pad.

2. The electronic device of claim 1,
wherein each of the straight grooves has one end oriented toward the center of the pad and another end extending to an edge of the pad.

3. The electronic device of claim 1,
wherein the plurality of straight grooves includes:
first straight grooves having a first length; and
second straight grooves having a second length shorter than the first length,
wherein the first straight grooves and the second straight grooves are alternately arranged along a circumferential direction of the pad.

4. The electronic device of claim 1,
wherein the plurality of straight grooves are arranged at angular intervals of 90 degrees or degrees in a circumferential direction.

5. The electronic device of claim 1,
wherein the pad further includes a plurality of curved grooves having an arc shape, and wherein the curved grooves are disposed between adjacent straight grooves.

6. The electronic device of claim 5,
wherein each of the curved grooves has opposite ends connected to adjacent straight grooves.

7. The electronic device of claim 5,
wherein each of the curved grooves has an arc shape with a central angle of 90 degrees or 45 degrees.

8. The electronic device of claim 5,
wherein the curved grooves are arranged to form concentric circles with the pad.

9. The electronic device of claim 5,
wherein the curved grooves include:
a plurality of first curved grooves; and
a plurality of second curved grooves disposed radially outward from the first curved grooves.

10. The electronic device of claim 9,
wherein the first curved grooves and the second curved grooves are concentric with each other.

11. The electronic device of claim 1,
wherein the pad has a circular outer profile.

12. The electronic device of claim 1,
wherein the straight grooves extend in a radial direction without intersecting each other.

13. The electronic device of claim 1,
wherein the straight grooves are uniformly spaced in a circumferential direction.

14. The electronic device of claim 5,
wherein each curved groove is positioned at a constant radial distance from the center of the pad.

15. The electronic device of claim 3,
wherein an inner end of each first straight groove is positioned closer to the center of the pad than an inner end of each second straight groove.

16. An electronic device comprising:
a printed circuit board; and
a pad disposed on a surface of the printed circuit board,
wherein the pad includes:
a plurality of straight grooves extending radially from a central region toward an outer edge of the pad; and
a plurality of arc-shaped curved grooves arranged between adjacent straight grooves and concentric with the pad.

17. The electronic device of claim 16,
wherein each curved groove has opposite ends connected to adjacent straight grooves.

18. The electronic device of claim 16,
wherein the curved grooves include a first set of curved grooves and a second set of curved grooves disposed radially outward from the first set.

19. The electronic device of claim 18,
wherein the first curved grooves and the second curved grooves are concentric with each other.

20. The electronic device of claim 16,
wherein the straight grooves are arranged at equal angular intervals of 45 degrees or 90 degrees around the center of the pad.
